(19) United States
(12) Patent Application Publication
(10) Pub. No.: US 2010/0177588 A1
(43) Pub. Date: Jul. 15, 2010

(54) CALIBRATION CIRCUIT AND CALIBRATION METHOD

(75) Inventors: Nakaba Kaiwa, Tokyo (JP); Yutaka Ikeda, Tokyo (JP); Hideyuki Yoko, Tokyo (JP)

Correspondence Address: MORRISON & FOERSTER LLP, 1650 TYSONS BOULEVARD, SUITE 400, MCLEAN, VA, 22102, US

(73) Assignee: Elpida Memory, Inc., Tokyo (JP)

(21) Appl. No.: 12/687,584

(22) Filed: Jan. 14, 2010

(30) Foreign Application Priority Data
Jan. 15, 2009 (JP) 2009-006534

(51) Int. Cl. G11C 8/18; H03L 7/00

(52) U.S. Cl. 365/233.11; 327/155; 327/160

(57) ABSTRACT

A calibration circuit includes replica buffers that have a substantially same circuit configuration as at least a part of an output buffer, an oscillator circuit that generates an internal clock in response to issuance of a calibration command, and a control circuit that controls an impedance of the replica buffers in synchronization with the internal clock. According to the present invention, because a calibration operation that does not depend on an external clock is performed, even when a frequency of the external clock is changed according to an operation mode or the like, it is possible to maintain a constant period of time given to a single adjustment step or a constant time required for a series of calibration operations.

### BACKGROUND OF THE INVENTION

1. Field of the Invention

The present invention relates to a calibration circuit and a calibration method, and more particularly relates to a calibration circuit that adjusts an impedance of an output buffer provided in a semiconductor device and a calibration method.

2. Description of Related Art

In recent years, a remarkably high data transfer rate is required for a data transfer between semiconductor devices (for example, between a CPU and a memory). In order to achieve the high transfer rate, amplitude of an input/output signal becomes much smaller. With the decrease of the amplitude of the input/output signal, the impedance accuracy required for an output buffer becomes considerably stringent.

The impedance of the output buffer not only fluctuates due to a process condition at the time of manufacture but also it is influenced by a change of an ambient temperature or a fluctuation of a power source voltage. Therefore, when high accuracy in impedance is required for the output buffer, it is necessary to use an output buffer with an impedance adjustment function (see Japanese Patent Application Laid-open No. 2008-135925). Such impedance adjustment for an output buffer is performed using a circuit generally called “calibration circuit”.

As described in Japanese Patent Application Laid-open Publication No. 2008-135925, the calibration circuit includes a replica buffer that has the same configuration as the output buffer. When performing a calibration operation, a voltage at a calibration terminal is compared with a reference voltage in a state that an external resistor is connected to the calibration terminal, and an impedance of the replica buffer is adjusted based a result of comparing the voltages. By reflecting the adjustment for the replica buffer in the output buffer, the impedance of the output buffer is set to a desired value.

In a series of calibration operations, an adjustment step including the comparison of voltages and updating of the impedance of the replica buffer is repeated for a plurality of times, so that the impedance of the replica buffer approaches a desired value.

However, because the comparison of voltages and the updating of the impedance of the replica buffer in the calibration process take a certain amount of time, when the frequency of an external clock is high, the adjustment step cannot be performed for every cycle of the external clock. To handle this problem, a conventional calibration circuit generates an internal clock having a lower frequency by frequency dividing the external clock, and then performs an adjustment step in synchronization with the internal clock.

Meanwhile, in some semiconductor devices, such as a DRAM (Dynamic Random Access Memory), the frequency of an external clock is not always fixed, but in some cases, the external clock changes according to an operation mode or the like. In such cases, with the conventional method of generating the internal clock by frequency dividing the external clock, the frequency of the internal clock also changes according to an operation mode or the like. Therefore, when the frequency of the external clock is high, a period of time given to a single adjustment step becomes short, which causes an operation margin to be stringent. On the contrary, when the frequency of the external clock is low, the period of time given to a single adjustment step becomes long, so that the time required for a series of calibration operations is increased.

### SUMMARY

The present invention seeks to solve one or more of the above problem, or to improve upon those problems at least in part.

In one embodiment, there is provided a calibration circuit that adjusts an impedance of an output buffer. The calibration circuit includes a replica buffer that has a substantially same circuit configuration as at least a part of the output buffer, an oscillator circuit that generates an internal clock in response to issuance of a calibration command and a control circuit that controls an impedance of the replica buffer in synchronization with the internal clock.

In another embodiment, there is provided a calibration circuit that adjusts an impedance of an output buffer included in a semiconductor device that performs input and output of data in synchronization with an external clock. The calibration circuit includes a replica buffer that has a substantially same circuit configuration as at least a part of the output buffer and a control circuit that controls an impedance of the replica buffer in synchronization with an internal clock that is desynchronized with the external clock.

In another embodiment, there is provided a calibration method of adjusting an impedance of an output buffer. The method includes a step of starting an operation of an oscillator circuit that generates an internal clock, in response to issuance of a calibration command and a step of adjusting an impedance of a replica buffer that has a substantially same circuit configuration as at least a part of the output buffer in synchronization with the internal clock.

According to the present invention, because a calibration operation is performed independent of an external clock, it is possible to maintain a constant period of time given to a single adjustment step and a constant time required for a series of calibration operations even when the frequency of the external clock changes with an operation mode or the like. Therefore, the present invention is suitable for applying to a semiconductor device, such as a DRAM, in which the frequency of an external clock changes according to an operation mode.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram of a calibration circuit according to an embodiment of the present invention;

FIG. 2 is a circuit diagram of the internal clock generating circuit;

FIG. 3 is a detailed circuit diagram of the internal clock generating circuit;

FIG. 4 is a circuit diagram of an internal clock generating circuit according to a modification of the present embodiment;

FIG. 5 is a constant current circuit that supplies a constant current to the oscillator circuit;

FIG. 6 is a circuit diagram of an oscillator circuit according to the modification of the present embodiment; and

FIG. 7 is a block diagram of the main parts of the semiconductor device including the calibration circuit.

### DETAILED DESCRIPTION OF THE EMBODIMENTS

Preferred embodiments of the present invention will be explained below in detail with reference to the accompanying drawings.

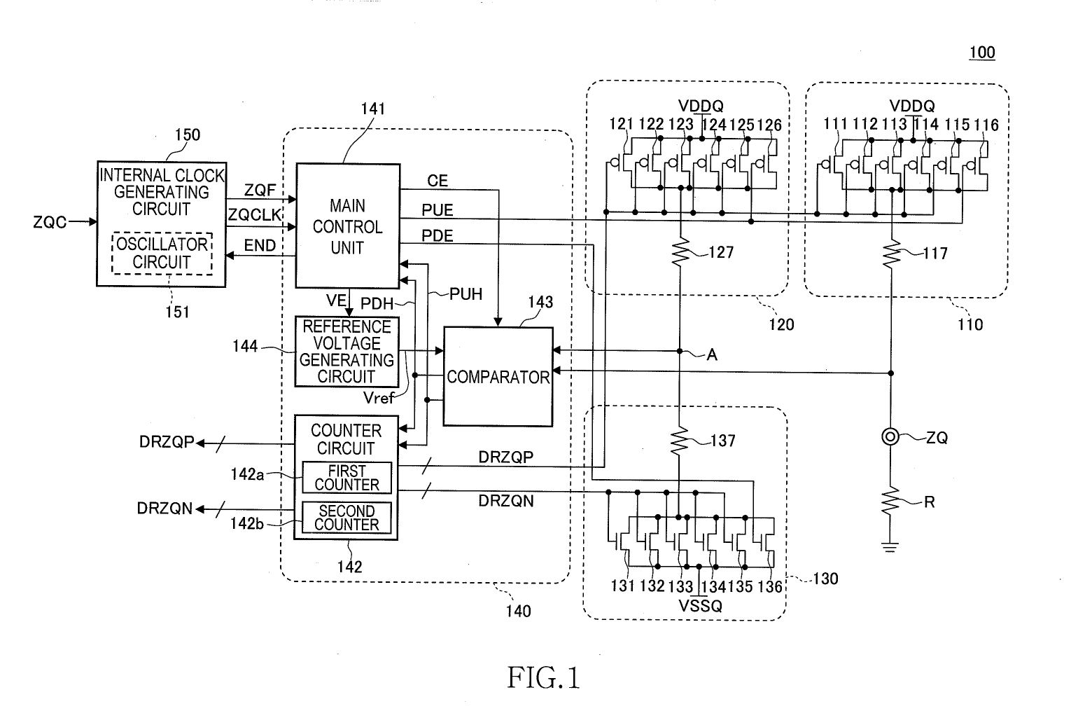

FIG. 1 is a block diagram of a calibration circuit 100 according to an embodiment of the present invention.

As shown in FIG. 1, the calibration circuit 100 according to the present embodiment includes replica buffers 110, 120, and 130, a control circuit 140, and an internal clock generating circuit 150. The control circuit 140 controls impedances of the replica buffers 110, 120, and 130 in synchronization with an internal clock ZQCLK that is generated by the internal clock generating circuit 150. The control circuit 140 includes a main control unit 141, a counter circuit 142, a comparator 143, and a reference voltage generating circuit 144.

Each of the replica buffers 110, 120, and 130 has the same circuit configuration as a part of an output buffer described later. An output impedance is adjusted by the replica buffers 110, 120, and 130, and the impedance of the output buffer is set to a desired value by reflecting a result of the adjustment in the output buffer. The adjustment of the impedance of the output buffer is the role of the calibration circuit 100.

Each of the replica buffers 110 and 120 includes six P-channel MOS transistors 111 to 116 and a resistor 117, and the replica buffer 120 includes six P-channel MOS transistors 121 to 126 and a resistor 127. The transistors 111 to 116 and 121 to 126 are connected in parallel to a power source line VDDQ. A terminal of the resistor 117 is connected to drains of the transistors 111 to 116, and a terminal of the resistor 127 is connected to drains of the transistors 121 to 126. Another terminal of the resistor 117 is connected to a calibration terminal ZQ, and another terminal of the resistor 127 is connected to an internal junction A. Each of the replica buffers 110 and 120 has only a pull-up function, without having a pull-down function.

A 5-bit impedance control signal DRZQP is supplied to gates of the transistors 111 to 115 and 121 to 125 by the counter circuit 142, by which the five transistors of the replica buffers 110 and 120 can be independently controlled on and off. Furthermore, a driver enable signal PUE is commonly supplied to gates of the transistors 116 and 126 by the main control unit 141.

The parallel circuits included in the replica buffers 110 and 120 are designed in such a manner that their impedances are set to a predetermined value (for example, 120Ω) when the circuits are switched on. However, because the ON resistance of a transistor fluctuates according to its manufacturing condition and changes with an ambient temperature or a power source voltage at the time of an operation, it is not always possible to achieve the desired impedance. Therefore, in order to actually achieve the impedance of 120Ω, it is necessary to adjust the number of transistors to be switched ON, which explains the purpose of using the parallel circuits configured with a plurality of transistors.

In order to achieve a fine adjustment of the impedance over a wide range, it is preferable that W/L (gate width/gate length) ratios of the plurality of transistors constituting the parallel circuit are set to differ from each other, and it is more preferable to use weighting of a power of two. Considering this aspect, in the present embodiment, the W/L ratios of the transistors 112 to 115 and 122 to 125 are set to 2P, 4P, 8P, and 16P, respectively, when the W/L ratios of the transistors 111 and 121 are set to P.

With this configuration, by appropriately selecting a transistor to be switched ON with the impedance control signal DRZQP, the ON resistance of the parallel circuit can be fixed to substantially 120Ω, regardless of the fluctuation due to manufacturing conditions or temperature change.

The resistances of the resistors 117 and 127 are designed to be 120Ω, for example. Therefore, when the parallel circuit including the transistors 111 to 116 is in an ON state, the impedance of the replica buffer 110 viewed from the calibration terminal ZQ becomes 240Ω. Furthermore, when the parallel circuit including the transistors 121 to 126 is in an ON state, the impedance of the replica buffer 120 viewed from the internal junction A becomes 240Ω. As for the resistors 117 and 127, for example, a tungsten (W) resistor can be used.

Meanwhile, the replica buffer 130 includes six N-channel MOS transistors 131 to 136 and a resistor 137. The transistors 131 to 136 are connected in parallel to a ground potential VSSQ. A terminal of the resistor 137 is connected to drains of the transistors 131 to 136, and another terminal of the resistor 137 is connected to the internal junction A. The replica buffer 130 has only a pull-down function, without having a pull-up function.

A 5-bit impedance control signal DRZQN is supplied to gates of the transistors 131 to 135 by the counter circuit 142, by which the five transistors included in the replica buffer 130 can be independently controlled on and off. Furthermore, a driver enable signal PDE is supplied to a gate of the transistor 136 from the main control unit 141.

The parallel circuit included in the replica buffer 130 is also designed in such a manner that its impedance is set to 120Ω, for example, when the circuits are switched on. Further, the resistance of the resistor 137 is also designed to be 120Ω, for example. With this configuration, when the parallel circuit including the transistors 131 to 136 is in an ON state, the impedance of the replica buffer 130 viewed from the internal junction A becomes 240Ω, similarly to the replica buffer 110.

As for the transistors 131 to 135, similarly to the transistors 111 to 115 and 121 to 125, it is particularly preferable that the W/L ratios are weighted with a power of two. Specifically, the W/L ratios of the transistors 132 to 135 are set to 2N, 4N, 8N, and 16N, respectively, when the W/L ratio of the transistor 131 is set to N.

As described above, the control circuit 140 includes the main control unit 141, the counter circuit 142, the comparator 143, and the reference voltage generating circuit 144.

The main control unit 141 is activated by a calibration flag ZQF, and when the main control unit 141 is activated, the driver enable signals PUE and PDE and a reference voltage enable signal VE are activated. The driver enable signals PUE and PDE activate the replica buffers 110, 120, and 130, which are supplied to the gate electrodes of the transistors 116, 126, and 136, as described above. The reference voltage enable signal VE is supplied to the reference voltage generating circuit 144, and upon receiving the reference voltage enable signal VE, the reference voltage generating circuit 144 generates a reference voltage Vref. The generated reference voltage Vref is supplied to the comparator 143.

Furthermore, when the main control unit 141 is activated, a comparator enable signal CE is successively activated in synchronization with an internal clock ZQCLK that is supplied from the internal clock generating circuit 150. By the comparator enable signal CE, the comparator 143 performs a comparison operation in synchronization with the internal clock ZQCLK.

The comparator 143 compares output voltages of the replica buffers 110, 120, and 130 (voltages at the calibration terminal ZQ and the internal junction A) with the reference voltage Vref. Specifically, the comparator 143 determines a logical level of a hit signal PUH based on a result of comparing the voltage of the calibration terminal ZQ with the reference voltage Vref, and determines a logical level of a hit signal PDH based on a result of comparing the voltage of the internal junction A with the reference voltage Vref. The hit signals PUH and PDH are supplied to the counter circuit 142.

The counter circuit 142 performs counting-up or counting-down based on the logical levels of the hit signals PUH and PDH. Specifically, the counter circuit 142 includes a first counter 142a and a second counter 142b, where the first counter 142a is counted up or counted down based on the logical level of the hit signal PUH, and the second counter 142b is counted up or counted down based on the hit signal PDH. The count value of the first counter 142a is used as the impedance control signal DRZQP, and the count value of the second counter 142b is used as the impedance control signal DRZQN. Therefore, the impedances of the replica buffers 110 and 120 are specified by the count value of the first counter 142a, and the impedance of the replica buffer 130 is specified by the count value of the second counter 142b.

The counter circuit 142 determines the count value of the first counter 142a first, and then determines the count value of the second counter 142b based on the count value of the first counter 142a. That is, the impedances of the replica buffers 110 and 120, which are the pull-up side, are determined by referring to the voltage at the calibration terminal ZQ, and then the impedance of the replica buffer 130, which is the pull-down side, is determined by referring to the voltage at the internal junction A.

As shown in FIG. 1, the internal clock generating circuit 150 includes an oscillator circuit 151 that generates the internal clock ZQCLK in response to issuance of a calibration command ZQC.

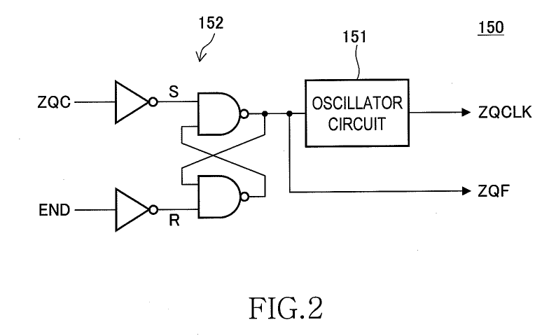

FIG. 2 is a circuit diagram of the internal clock generating circuit 150.

As shown in FIG. 2, the internal clock generating circuit 150 includes an SR latch 152 and the oscillator circuit 151. The calibration command ZQC is input to the set terminal (S) of the SR latch 152, and an end signal END is input to the reset terminal (R) of the SR latch 152. The oscillator circuit 151 is activated based on the calibration flag ZQF that is an output of the SR latch 152. The end signal END is a signal for instructing an end of a calibration operation after a lapse of a predetermined period of time since the calibration command ZQC is issued. Although not limited thereto, in the present embodiment, the end signal END is generated in response to a predetermined count of the internal clock ZQCLK.

With the above circuit configuration, when the calibration command ZQC, which is a one-shot pulse, is activated, the SR latch 152 is set, so that the calibration flag ZQF is activated to a High level. The oscillator circuit 151 then starts to generate the internal clock ZQCLK, and activates the main control unit 141 at the same time. Thereafter, when the end signal END, which is a one-shot pulse, is activated, the SR latch 152 is reset, so that the calibration flag ZQF is deactivated to a Low level. The oscillator circuit 151 then ends its operation, and at the same time, deactivates the main control unit 141.

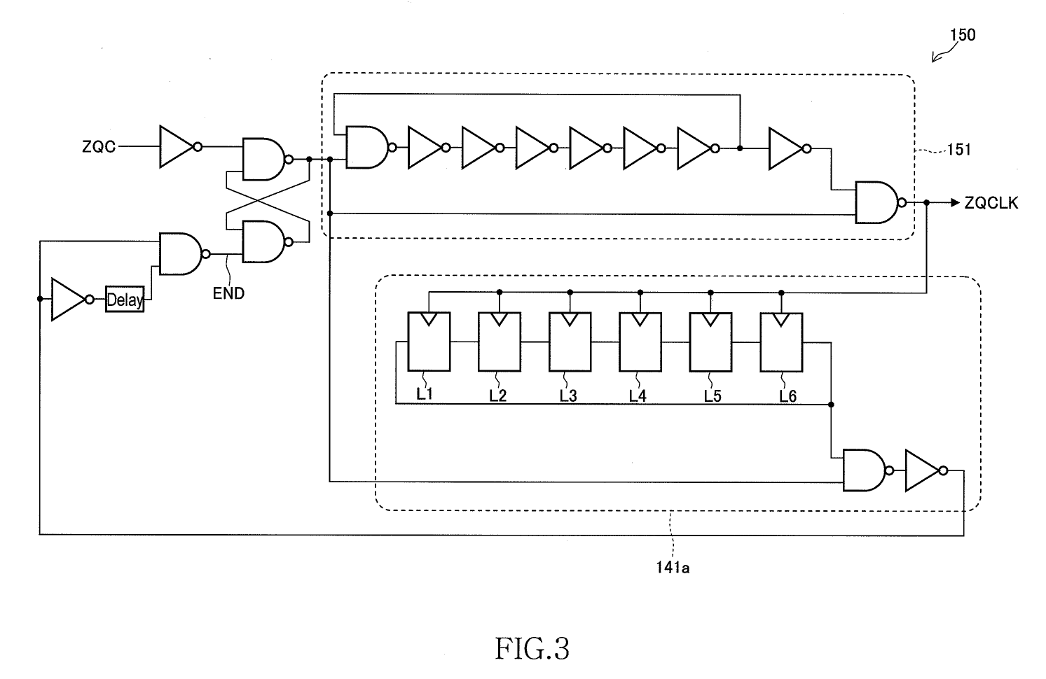

FIG. 3 is a detailed circuit diagram of the internal clock generating circuit 150.

As shown in FIG. 3, the oscillator circuit 151, which is included in the internal clock generating circuit 150, is configured with a ring oscillator in which a plurality of inverters are connected in a ring pattern. Therefore, the frequency of the internal clock ZQCLK that is generated by the oscillator circuit 151 is determined by the number of the inverters connected in the ring pattern and their capacities. That is, the frequency of the internal clock ZQCLK is independent of an external clock, and the internal clock ZQCLK and the external clock are desynchronized with each other. Although not limited thereto, the external clock is a clock that defines input and output timings of data in a semiconductor memory such as a DRAM, of which the frequency is different according to an operation mode or the like.

An end signal generating circuit 141a shown in FIG. 3 is included in the main control unit 141, which generates the end signal END in response to a predetermined count of the internal clock ZQCLK. In the example shown in FIG. 3, the end signal generating circuit 141a includes six latch circuits L1 to L6 that are connected in a cascaded manner, by which the end signal END is activated when the internal clock ZQCLK is counted by 64 (=2⁶).

As described above, because the main control unit 141 activates the comparator enable signal CE in synchronization with the internal clock ZQCLK, when the calibration command ZQC is activated, 64 times of adjustment steps are performed by using the counter circuit 142 and the comparator 143, which completes a series of calibration operations.

In this manner, in the calibration circuit 100 according to the present embodiment, the internal clock ZQCLK, which is independent of the external clock, is generated by the oscillator circuit 151, and a series of calibration operations are performed in synchronization with the internal clock ZQCLK. Therefore, a period of time given to a single adjustment step and a period of time required for a series of calibration operations are kept constant regardless of the frequency of the external clock.

Therefore, even when the frequency of the external clock is high, the period of time given to a single adjustment step does not become shorter. On the contrary, even when the frequency of the external clock is low, the time required for a series of calibration operations does not become longer. Accordingly, in a semiconductor device, such as a DRAM, in which the frequency of the external clock is different according to its operation mode, it is possible to maintain the calibration condition regardless of the frequency of the external clock.

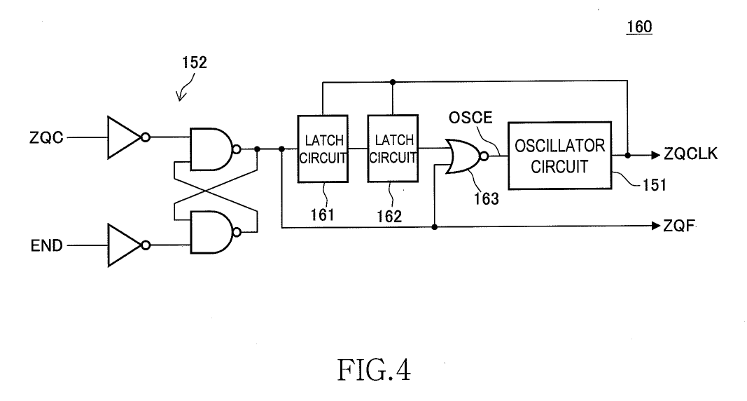

FIG. 4 is a circuit diagram of an internal clock generating circuit 160 according to a modification of the present embodiment. The internal clock generating circuit 160 can be used as an alternative to the internal clock generating circuit 150 described above.

The internal clock generating circuit 160 shown in FIG. 4 has a configuration in which two latch circuits 161 and 162 that are connected in a cascaded manner and a NOR circuit 163 are added between the SR latch 152 and the oscillator circuit 151. The latch circuits 161 and 162 take input signals in synchronization with the internal clock ZQCLK that is an output of the oscillator circuit 151. The NOR circuit 163 receives an output signal of the latch circuit 162 and the calibration flag ZQF, and outputs an oscillator enable signal OSCE. The generated oscillator enable signal OSCE is supplied to the oscillator circuit 151, and based thereon the oscillator circuit 151 is activated.

With this configuration, the internal clock ZQCLK is output by two cycles even after the end signal END is activated. Accordingly, even when the calibration circuit 100 includes a circuit that latches the end signal END using the internal clock ZQCLK as a trigger, for example, it is possible to operate such a circuit correctly.

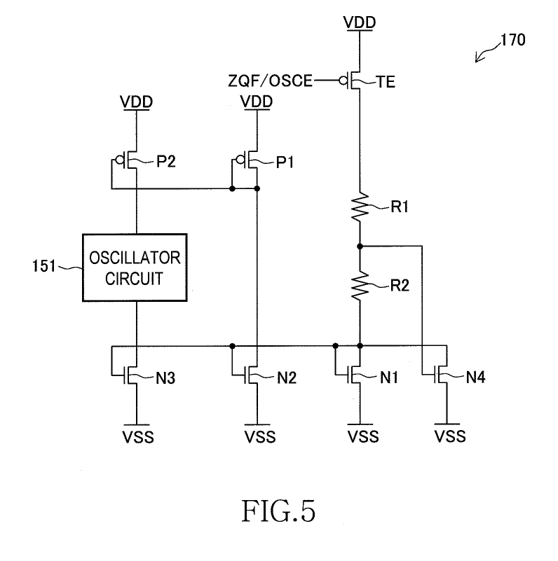

FIG. 5 is a constant current circuit 170 that supplies a constant current to the oscillator circuit 151.

The constant current circuit 170 shown in FIG. 5 is a circuit that is connected between a pair of power supply lines VDD and VSS, and includes a transistor TE, resistors R1 and R2, and a transistor N1 that are connected in series, transistors N2 and N3 that form a current mirror circuit with the transistor N1, a transistor P1 that is connected in series with the transistor N2, and a transistor P2 that forms a current mirror circuit with the transistor P1. The oscillator circuit 151 is connected between the transistor P2 and the transistor N3, by which a constant current is supplied to the oscillator circuit 151.

The constant current circuit 170 further includes a transistor N4 that is connected in parallel to the transistor N1. A gate of the transistor N4 is connected to a junction of the resistors R1 and R2. With this configuration, the transistor N4 forms a feedback circuit that adjusts an amount of the constant current based on a voltage between the power source lines VDD and VSS. Specifically, when the voltage between the power source lines VDD and VSS is decreased, the ON resistance of the transistor N4 is increased, and an input voltage to the current mirror circuit is increased. As a result, a correction is taken such that the amount of the constant current is increased. On the other hand, when the voltage between the power source lines VDD and VSS is increased, the ON resistance of the transistor N4 is decreased, and the input voltage to the current mirror circuit is decreased. As a result, a correction is taken such that the amount of the constant current is decreased.

In this manner, because the power source voltage dependence of the period of the internal clock ZQCLK is relieved, it is possible to provide more stabilization on the period of the internal clock ZQCLK.

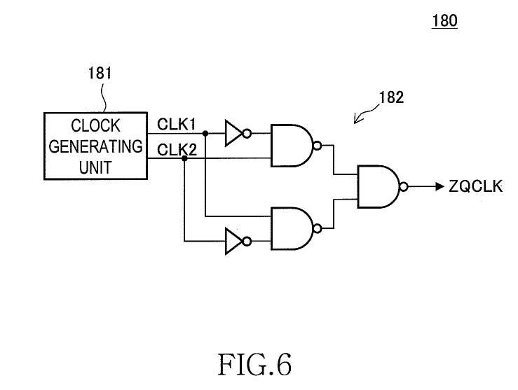

FIG. 6 is a circuit diagram of an oscillator circuit 180 according to the modification of the present embodiment. The oscillator circuit 180 can be used as an alternative to the oscillator circuit 151 described above.

The oscillator circuit 180 shown in FIG. 6 includes a clock generating unit 181 and a clock combining unit 182, where the clock generating unit 181 generates intermediate clocks CLK1 and CLK2 having different phases from each other, and the clock combining unit 182 generates the internal clock ZQCLK that has a frequency higher than frequencies of the intermediate clocks CLK1 and CLK2, based on the intermediate clocks CLK1 and CLK2.

With this configuration, because the intermediate clocks CLK1 and CLK2 having lower frequencies are generated, it is possible to reduce the level difference of the intermediate clocks CLK1 and CLK2. As a result, a higher precision can be achieved even for the period of the internal clock ZQCLK that is finally obtained.

Main parts of a semiconductor device 200 including the calibration circuit 100 according to the present embodiment are explained below.

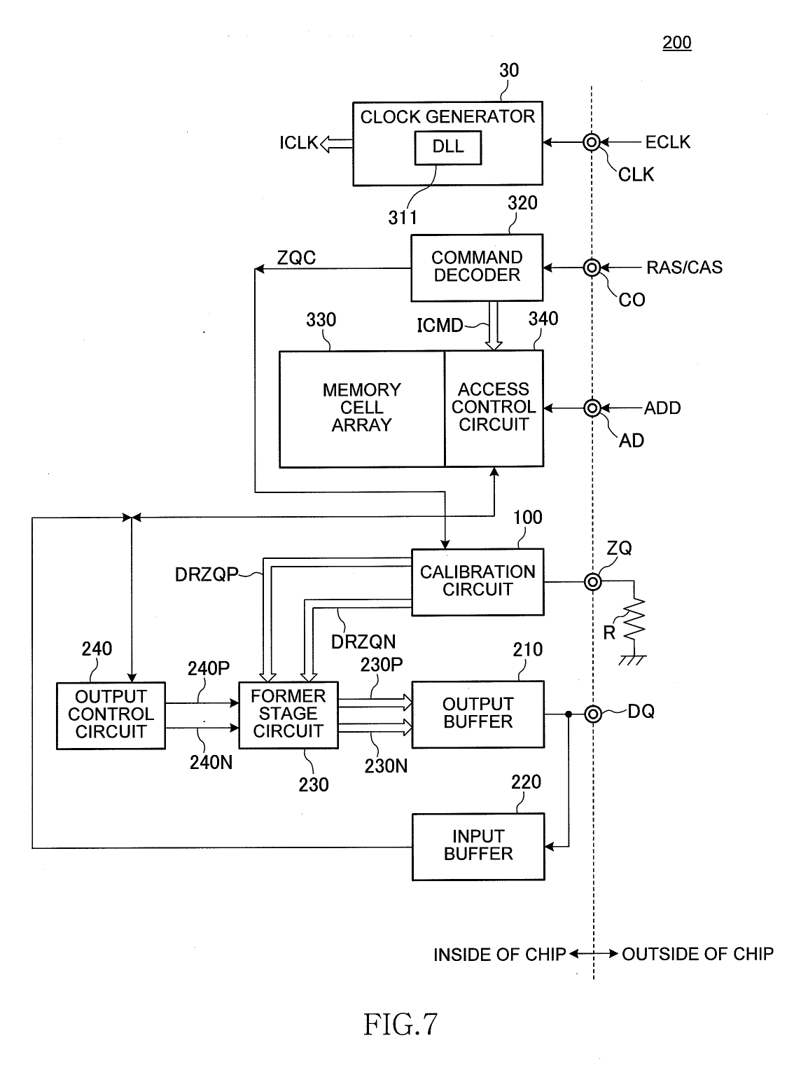

FIG. 7 is a block diagram of the main parts of the semiconductor device 200 including the calibration circuit 100.

The semiconductor device 200 shown in FIG. 7 includes an output buffer 210 and an input buffer 220 that are connected to a data input/output terminal DQ, in addition to the calibration circuit 100. The semiconductor device 200 further includes a clock generator 310, a command decoder 320, a memory cell array 330, and an access control circuit 340.

The clock generator 310 includes a DLL circuit 311 that generates an internal clock signal ICLK based on an external clock signal ECLK supplied from outside via a clock terminal CLK. Thus, the internal clock signal ICLK is generated in synchronism with an external clock signal ECLK. The internal clock signal ICLK is a timing signal used to perform the data read operation and the data write operation. The internal clock signal ICLK is not supplied to the calibration circuit 100 because the calibration circuit 100 can generate the internal clock ZQCLK by themselves using the oscillator circuit 151 shown in FIG. 1. Thus, the internal clock ZQCLK is generated in asynchronously with the external clock signal ECLK.

The command decoder 320 receives RAS (Row Address Strove) signal, CAS (Column Address Strove) signal and the other external command signal that are supplied from outside via a command terminal CO. The command decoder 320 decodes these external command signal to generate an internal command ICMD. When the external command signal is a calibration command, the command decoder 320 activates the internal calibration command ZQC (calibration active signal). The calibration command ZQC is supplied to the calibration circuit 100. The other internal command ICMD is supplied to the access control circuit 340.

The memory cell array 330 includes a plurality of DRAM cells each constituted of a single cell transistor and a single cell capacitor. The access control circuit 340 performs the data read operation or the data write operation on the memory cell array 330 based on the internal command ICMD and an address signal ADD supplied from outside via an address terminal AD. The access control circuit 340 includes an address buffer, a row decoder, a column decoder, word line drivers, sense amplifiers, and column switches. A write data to be written to the memory cell selected by the row decoder and the column decoder is supplied from outside via the data input/output terminal DQ and the input buffer 220. A read data read from the memory cell selected by the row decoder and the column decoder is supplied to outside via the output buffer 210 and the data input/output terminal DQ.

An operation of the output buffer 210 is controlled by operation signals 230P and 230N that are supplied from a former stage circuit 230. As shown in FIG. 7, the impedance control signals DRZQP and DRZQN are supplied to the former stage circuit 230 from the calibration circuit 100. Furthermore, an external resistor R is connected to the calibration terminal ZQ.

Although not shown in the drawings, the output buffer 210 includes a pull-up circuit that includes six P-channel MOS transistors connected in parallel and a pull-down circuit that includes six N-channel MOS transistors connected in parallel. The pull-up circuit has a substantially same circuit configuration as the replica buffers 110 and 120, and the pull-down circuit has a substantially same circuit configuration as the replica buffer 130. The pull-up circuit is controlled by the operation signal 230P, and the pull-down circuit is controlled by the operation signal 230N. The operation signal 230P is activated by a select signal 240P that is supplied from an output control circuit 240, of which the value is determined based on the impedance control signal DRZQP. The operation signal 230N is activated by a select signal 240N that is supplied from the output control circuit 240, of which the value is determined based on the impedance control signal DRZQN.

With this configuration, the impedance of the output buffer 210 becomes the same value as the adjusted impedance obtained by the calibration circuit 100.

It is apparent that the present invention is not limited to the above embodiments, but may be modified and changed without departing from the scope and spirit of the invention.

For example, the size of the transistor that constitutes the replica buffers 110, 120, and 130 does not have to be the same as the size of the transistor that constitutes the output buffer 210. As far as the impedances of these transistors are substantially the same, a shrunk transistor can be used. That is, the replica buffers do not have to have exactly the same circuit configuration as that of the output buffer, and it suffices that the replica buffers have a substantially same circuit configuration as at least a part of the output buffer.

What is claimed is:

1. A semiconductor device with a calibration circuit that adjusts an impedance of an output buffer, the calibration circuit comprising:
a replica buffer that has a substantially same circuit configuration as at least a part of the output buffer;
an oscillator circuit that generates an internal clock in response to issuance of a calibration command; and
a control circuit that controls an impedance of the replica buffer in synchronization with the internal clock.

2. The device as claimed in claim 1, wherein the oscillator circuit is a ring oscillator.

3. The device as claimed in claim 1, wherein
the control circuit includes a comparator that compares an output voltage of the replica buffer with a reference voltage, and a counter circuit that counts up or counts down based on a result of comparing the voltages by the comparator, and
the impedance of the replica buffer is controlled based on a count value of the counter circuit.

4. The device t as claimed in claim 3, wherein the control circuit further includes an end signal generating circuit that generates an end signal for indicating an end of a calibration operation after a lapse of a predetermined period of time since issuance of the calibration command.

5. The device as claimed in claim 4, wherein the end signal generating circuit generates the end signal in response to a predetermined count of the internal clock.

6. The device as claimed in claim 4, wherein the oscillator circuit stops an operation based on the end signal.

7. The device as claimed in claim 6, wherein the oscillator circuit stops an operation after a lapse of a predetermined period of time since the end signal is activated.

8. The device as claimed in claim 1, further comprising a constant current circuit that is connected between a pair of power source lines and that supplies a constant current to the oscillator circuit, wherein
the constant current circuit includes a feedback circuit that adjusts an amount of the constant current based on a voltage between the power source lines.

9. The device as claimed in claim 1, wherein the oscillator circuit includes:
a clock generating unit that generates a plurality of intermediate clocks having different phases from each other; and
a clock combining unit that generates, based on the intermediate clocks, the internal clock that has a frequency higher than frequencies of the intermediate clocks.

10. A semiconductor device with a calibration circuit that adjusts an impedance of an output buffer included in a semiconductor device that performs input and output of data in synchronization with an external clock, the calibration circuit comprising:
a replica buffer that has a substantially same circuit configuration as at least a part of the output buffer; and
a control circuit that controls an impedance of the replica buffer in synchronization with an internal clock that is desynchronized with the external clock.

11. A semiconductor device comprising:
a first clock circuit generating a first clock signal;
a memory cell array;
a data access circuit performing a data read/write operation on the memory cell array in response to the first clock signal;
a second clock circuit provided separately from the first clock circuit and generating a second clock signal; and
a calibration circuit performing an impedance calibration operation in response to the second clock signal.

12. The device as claimed in claim 11, wherein the data access circuit includes a command decoder, the command decoder producing a calibration active signal in response to a calibration command, the second clock circuit being activated in response to the calibration active signal to produce the second clock signal.

13. The device as claimed in claim 12, wherein the calibration circuit includes a flag circuit that is brought into a first state in response to the calibration active signal and into a second state when the calibration operation is suspended.

14. The device as claimed in claim 11, wherein the second clock signal has a substantially constant frequency.

15. The device as claimed in claim 13, wherein the first clock signal is generated in synchronism with an external clock signal supplied to the device and the second signal is generated in asynchronously with the external clock signal.
